(19) United States
(12) Patent Application Publication
(10) Pub. No.: US 2026/0040998 A1
(43) Pub. Date: Feb. 5, 2026

(54) MICRO LIGHT-EMITTING DIODE DISPLAY UNIT

(71) Applicant: PlayNitride Display Co., Ltd., MiaoLi County (TW)

(72) Inventors: Kun-Pei Lin, MiaoLi County (TW); Wei-Ping Lin, MiaoLi County (TW); Po-Jen Su, MiaoLi County (TW)

(73) Assignee: PlayNitride Display Co., Ltd., MiaoLi County (TW)

(21) Appl. No.: 18/923,630

(22) Filed: Oct. 22, 2024

(30) Foreign Application Priority Data
Aug. 2, 2024 (TW) 113128915

(51) Int. Cl. H01L 25/16; H01L 23/00; H01L 23/13; H01L 23/498; H01L 25/075; H01L 33/52; H01L 33/62

(52) U.S. Cl. CPC H01L 25/167; H01L 23/13; H01L 23/49827; H01L 24/16; H01L 24/20; H01L 24/48; H01L 25/0753; H10H 20/852; H10H 20/857; H01L 2224/16145; H01L 2224/211; H01L 2224/48227; H01L 2924/12041; H01L 2924/1426; H10H 20/0362; H10H 20/0364

(57) ABSTRACT

A micro light-emitting diode display unit including a driving chip, at least one pixel, and a conductor is disclosed. The pixel includes multiple micro light-emitting diodes (micro-LEDs) disposed on a top of the driving chip. Orthogonal projections of the micro-LEDs are all covered by an orthogonal projection of the driving chip. The conductor is disposed at an outer side of the driving chip, and extends from a side adjacent to a top portion of the driving chip on which the micro-LEDs are disposed to a side away from the micro-LEDs, and is connected to an outside circuit. A manufacturing method of a micro light-emitting diode display unit is also disclosed.

### CROSS-REFERENCE TO RELATED APPLICATION

This application claims the priority benefit of Taiwan application serial no. 113128915, filed on Aug. 2, 2024. The entirety of the above-mentioned patent application is hereby incorporated by reference herein and made a part of this specification.

### BACKGROUND

### Technical Field

This disclosure relates to a display unit and a manufacturing method thereof, and in particular, to a micro light-emitting diode display unit and a manufacturing method thereof.

### Description of Related Art

With the advancement of display technology, micro light-emitting diode (LED) displays have been developed. The micro LED displays can be manufactured by first growing a semiconductor stack structure of micro LEDs on a growth substrate, then transferring the micro LEDs to a transfer substrate, and finally transferring and bonding the micro LEDs on the transfer substrate to a circuit substrate to form a display panel.

However, in the known manufacturing method of the micro LED displays, the number of micro LEDs to be transferred to the circuit substrate has to be matched with the number of existing driving chips on the circuit substrate, and it is not possible to freely form various display panels with different resolutions. In addition, when the micro LEDs are transferred to the circuit substrate, they need to be aligned with the driving chips, which limits the manufacturing speed and makes it difficult to increase the speed.

### SUMMARY

The disclosure provides a micro light-emitting diode display unit, which can be easily used to manufacture micro light-emitting diode displays, can be freely form into a variety of displays with different resolutions, and can accelerate a manufacturing speed of module sections.

The disclosure provides a manufacturing method of a micro light-emitting diode display unit, in which the resulting micro light-emitting diode display unit can be easily used to manufacture micro light-emitting diode displays, can be freely form into a variety of displays with different resolutions, and can accelerate a manufacturing speed of module sections.

An embodiment of the disclosure proposes a micro light-emitting diode display unit, including a driving chip, at least one pixel, and a conductor. The pixel includes multiple micro light-emitting diodes disposed on a top portion of the driving chip. Orthogonal projections of the micro light-emitting diodes are covered by an orthogonal projection of the driving chip. The conductor is disposed at an outer side of the driving chip, extends from a side adjacent to the top portion of the driving chip on which the micro light-emitting diodes are disposed to a side far away from the micro light-emitting diodes, and is connected to an outside circuit.

An embodiment of the disclosure proposes a manufacturing method of a micro light-emitting diode display unit, which includes the following. A first relay substrate is provided and a circuit layer is disposed on the first relay substrate. Multiple micro light-emitting diodes are transferred to the first relay substrate, and the micro-light-emitting diodes are connected to the circuit layer. A light-shielding layer is disposed between the micro light-emitting diodes. A packaging material is disposed to cover the micro light-emitting diodes and the circuit layer, and a second relay substrate is disposed on the packaging material. The first relay substrate is removed. A solder mask layer is disposed on the circuit layer. A solder is provided to the circuit layer. A driving chip is soldered to the circuit layer. A carrier is manufactured by a dry film, the carrier covers the driving chip and carries the micro light-emitting diodes.

In the micro light-emitting diode display unit and the manufacturing method thereof according to the embodiments of the disclosure, since the driving chip and the micro light-emitting diode are paired to form a display unit, when such a micro light-emitting diode display unit is later assembled into a display, by assembling the required number of micro light-emitting diode display units, a variety of displays with different resolutions or ratios can be freely formed. In addition, since the micro light-emitting diode display unit has its own driving chip, there is no need to consider matching the number of the micro light-emitting diodes with the number of the driving chips on the circuit substrate as in the conventional technology, and there is no need for the display unit to be additionally aligned with the driving chip on the circuit substrate as in the conventional technology, so that the manufacturing speed of the module section may be effectively increased.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate example embodiments of the disclosure and, together with the description, serve to explain the principles of the disclosure.

FIG. 1 is a schematic cross-sectional view of a micro light-emitting diode display unit according to an embodiment of the disclosure.

FIG. 2 is a schematic cross-sectional view of a micro light-emitting diode display unit according to another embodiment of the disclosure.

FIG. 3 is a schematic cross-sectional view of a micro light-emitting diode display unit according to still another embodiment of the disclosure.

FIG. 4 is a schematic cross-sectional view of a micro light-emitting diode display unit according to yet another embodiment of the disclosure.

FIG. 5 is a schematic cross-sectional view of a micro light-emitting diode display unit according to another embodiment of the disclosure.

FIG. 6 is a schematic cross-sectional view of a micro light-emitting diode display unit according to still another embodiment of the disclosure.

FIG. 7 is a schematic cross-sectional view of a micro light-emitting diode display unit according to yet another embodiment of the disclosure.

FIG. 8 is a schematic cross-sectional view of a micro light-emitting diode display unit according to another embodiment of the disclosure.

FIG. 9 is a schematic cross-sectional view of a micro light-emitting diode display unit according to still another embodiment of the disclosure.

FIG. 10 is a schematic cross-sectional view of a micro light-emitting diode display unit according to yet another embodiment of the disclosure.

FIG. 11 is a schematic cross-sectional view of a micro light-emitting diode display unit according to another embodiment of the disclosure.

FIG. 12A is a schematic cross-sectional view of a group of micro light-emitting diodes in FIG. 11.

FIG. 12B is a schematic cross-sectional view of a group of micro light-emitting diodes of FIG. 11 according to another embodiment.

FIG. 13 is a schematic cross-sectional view of multiple micro light-emitting diode display units of FIG. 3 bonded to a circuit substrate.

FIG. 14A to FIG. 14J are schematic cross-sectional views illustrating a process of a manufacturing method of a micro light-emitting diode display unit according to an embodiment of the disclosure.

### DESCRIPTION OF THE EMBODIMENTS

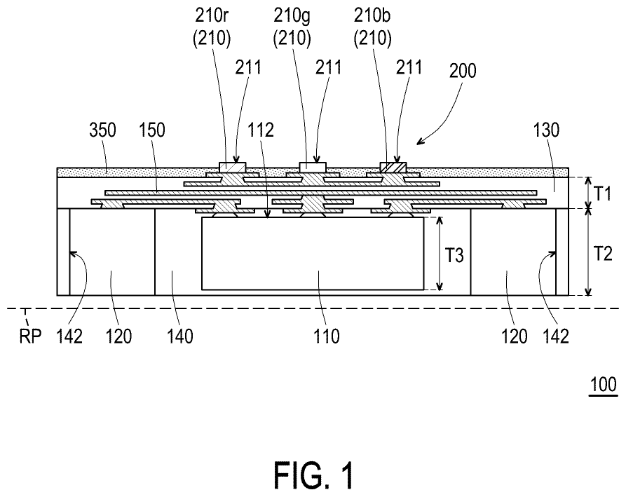

FIG. 1 is a schematic cross-sectional view of a micro light-emitting diode display unit according to an embodiment of the disclosure. Referring to FIG. 1, a micro light-emitting diode display unit 100 of this embodiment includes a driving chip 110, at least one pixel 200 (FIG. 1 shows an example of one pixel 200), and at least one conductor 120 (FIG. 1 shows an example of two conductors 120). The pixel 200 includes multiple micro light-emitting diodes 210, which are disposed on a top portion 112 of the driving chip 110. Among the micro light-emitting diodes 210 in FIG. 1, a micro light-emitting diode 210r is, for example, a red light micro-light emitting diode chip, a micro light-emitting diode 210g is, for example, a green light micro-light emitting diode chip, and a micro-light emitting diode 210b is, for example, a blue micro light-emitting diode chip, but the disclosure is not limited thereto. In other embodiments, the micro light-emitting diodes 210 can also be micro light-emitting diode chips with other color combinations. A light-shielding layer 350 is disposed between the micro light-emitting diodes 210 to avoid optical crosstalk.

Orthogonal projections of the micro light-emitting diodes 210 are covered by an orthogonal projection of the driving chip 110. Specifically, the orthogonal projections of the micro light-emitting diodes 210 on a reference plane RP parallel to the driving chip 110 are covered by the orthogonal projection of the driving chip 110 on the reference plane RP. In one embodiment, orthogonal projections of multiple light-emitting surfaces 211 of the micro light-emitting diodes 210 are covered by the orthogonal projection of the driving chip 110. The conductor 120 is disposed at an outer side of the driving chip 110, extends from a side adjacent to the top portion 112 of the driving chip 110 on which the micro light-emitting diodes 210 are disposed to a side far away from the micro light-emitting diodes 210, and is connected to an outside circuit. The outside circuit is, for example, a circuit on a circuit substrate, and the conductor 120 is electrically connected to the circuit substrate downwards. In this embodiment, the conductor 120 does not interfere with light emitting paths of the micro light-emitting diodes 210.

In the micro light-emitting diode display unit 100 of this embodiment, since the driving chip 110 and the micro light-emitting diode 210 are paired to form a micro light-emitting diode display unit 100, which is also known as micro LED in Package (MIP), when such a micro light-emitting diode display unit 100 is later assembled into a display, by assembling the required number of micro light-emitting diode display units 100, a variety of displays with different resolutions or ratios can be freely formed. In addition, since the micro light-emitting diode display unit 100 has its own driving chip, there is no need to consider matching the number of the micro light-emitting diodes 210 with the number of the driving chips on the circuit substrate as in the conventional technology, and there is no need for the display unit to be additionally aligned with the driving chip on the circuit substrate as in the conventional technology, so that the manufacturing speed of the module section may be effectively increased.

In this embodiment, the micro light-emitting diode display unit 100 further includes a carrier 140, in which the driving chip 110 is disposed in the carrier 140. In this embodiment, the carrier 140 has at least one through hole 142 (FIG. 1 shows an example of two through holes 142), and the conductor 120 is disposed in the through hole 142. The conductor 120 is, for example, a copper pillar. However, in other embodiments, the conductor 120 can also be solder balls, solder paste, or other suitable conductive materials, which can be selectively coated during the back-end process to increase flexibility. In this embodiment, the micro light-emitting diode display unit 100 further includes a circuit layer 150, which is disposed between the micro light-emitting diodes 210 and the driving chip 110, and connects the conductor 120 and the driving chip 110.

In this embodiment, the micro light-emitting diode display unit 100 includes a redistribution layer 130 disposed between the driving chip 110 and the micro light-emitting diodes 210, and the micro light-emitting diodes 210 are electrically connected to driving chip 110. In this embodiment, the circuit layer 150 may be a part of the redistribution layer 130, or the circuit layer 150 is the redistribution layer 130. The conductor 120 can be integrally formed with the redistribution layer 130 during the photolithography process to improve reliability.

In this embodiment, a thickness T1 of the redistribution layer 130 is less than 50% of a thickness T2 of the carrier 140. In addition, in this embodiment, a thickness T3 of the driving chip 110 is greater than 70% of the thickness T2 of the carrier 140.

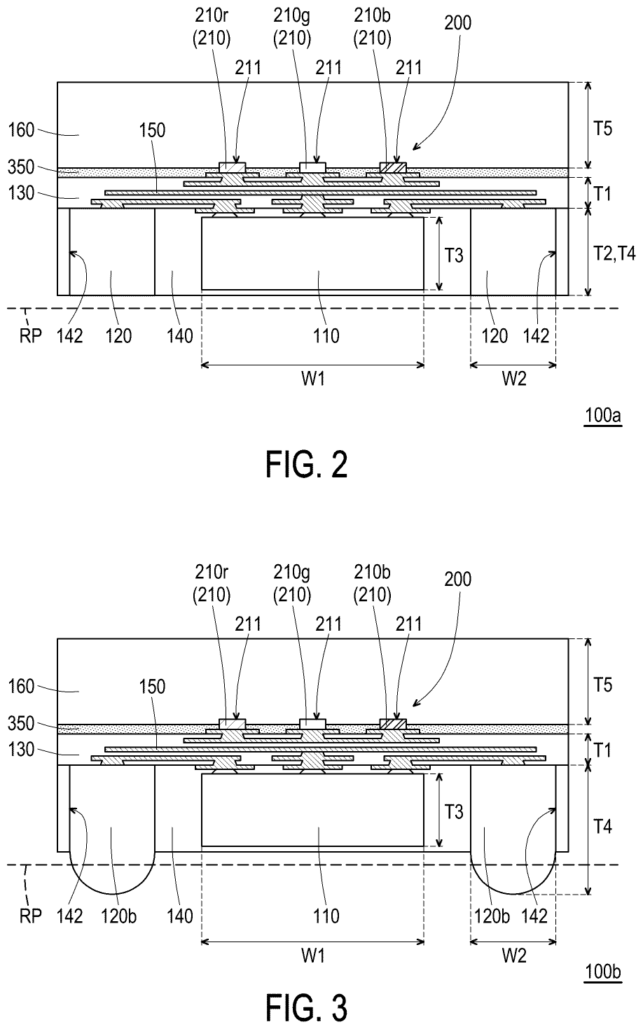

FIG. 2 is a schematic cross-sectional view of a micro light-emitting diode display unit according to another embodiment of the disclosure. Referring to FIG. 2, a micro light-emitting diode display unit 100a of this embodiment is similar to the micro light-emitting diode display unit 100 of FIG. 1, and the main differences between the two are as follows. The micro light-emitting diode display unit 100a of this embodiment further includes a packaging material 160 disposed above the micro light-emitting diodes 210. The packaging material 160 may be a transparent material. In this embodiment, the packaging material 160 is, for example, epoxy resin.

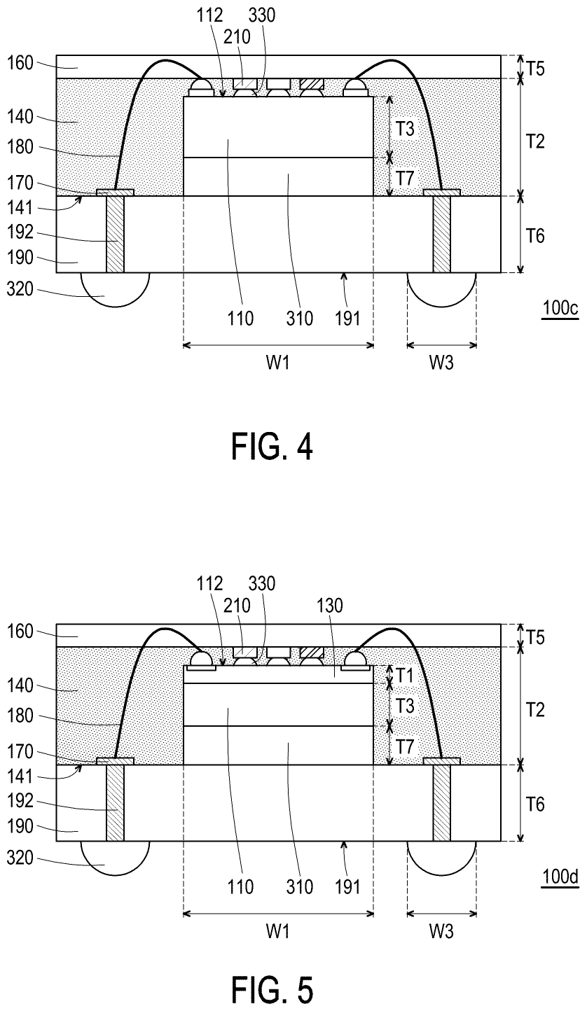

In one embodiment, the thickness T1 of the redistribution layer 130 is, for example, about 10 to 30 microns, the thickness T2 of the carrier 140 is, for example, 80 to 100 microns, the thickness T3 of the driving chip 110 is, for example, about 60 to 80 microns, and a thickness T5 of the packaging material 160 is, for example, 80 to 100 microns, a height T4 of the conductor 120 is, for example, 80 to 100 microns, a width W1 of the driving chip 110 is, for example, about 200 to 250 microns, and a width W2 of the conductor 120 is, for example, 80 to 100 microns. FIG. 3 is a schematic cross-sectional view of a micro light-emitting diode display unit according to still another embodiment of the disclosure. Referring to FIG. 3, a micro light-emitting diode display unit 100b of this embodiment is similar to the micro light-emitting diode display unit 100a of FIG. 2. The main difference between the two is that in the micro light-emitting diode display unit 100b of this embodiment, a conductor 120b is a solder ball or solder paste, which can be selectively coated during the back-end process to improve flexibility.

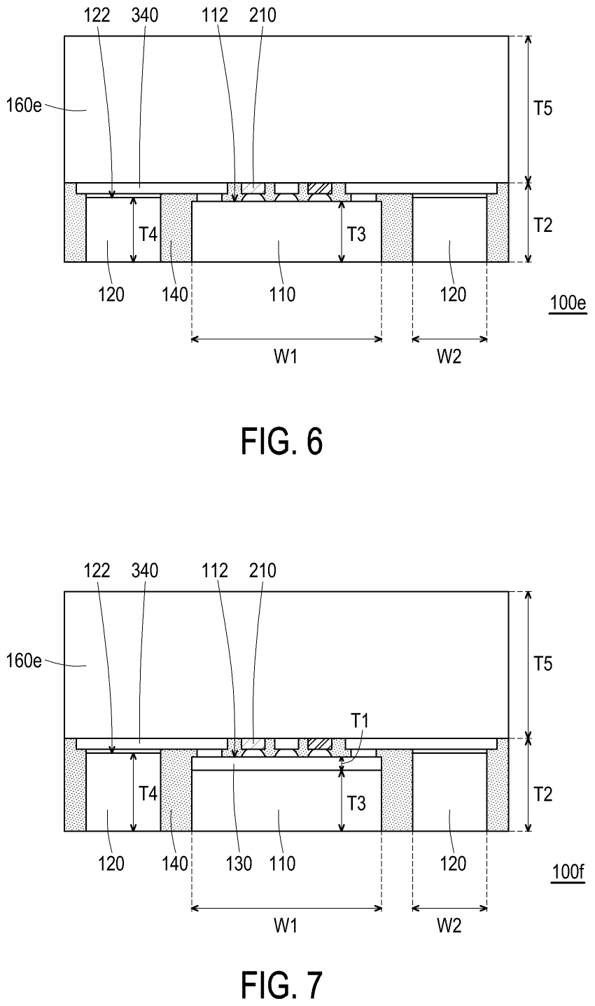

FIG. 4 is a schematic cross-sectional view of a micro light-emitting diode display unit according to yet another embodiment of the disclosure. Referring to FIG. 4, a micro light-emitting diode display unit 100c of this embodiment is similar to the micro light-emitting diode display unit 100a of FIG. 2, and the main differences between the two are as follows. The micro light-emitting diode display unit 100c of this embodiment further includes at least one contact pad 170 (FIG. 4 shows an example of two contact pads 170), and the conductor is at least one metal wire 180 (FIG. 4 shows an example of two metal wires 180). The contact pads 170 are disposed on a lower surface 141 of the carrier 140, and the metal wires 180 connect the top portion 112 of the driving chip 110 and the contact pads 170.

In this embodiment, the carrier 140 can be disposed on a substrate 190, and the driving chip 110 can be attached to the substrate 190 through a thermally conductive tape 310. A conductive via 192 may be provided in the substrate 190, and the pad 170 is connected to a pin 320 located on a lower surface 191 of the substrate 190 through the conductive via 192. The pin 320 can be electrically connected to the outside circuit (i.e., the circuit of the circuit substrate).

In addition, in this embodiment, the micro light-emitting diodes 210 can be electrically connected to the driving chip 110 through multiple bumps 330 respectively.

In one embodiment, the thickness T5 of the packaging material 160 is, for example, about 10 to 30 microns, the thickness T2 of the carrier 140 is, for example, about 130 to 150 microns, a thickness T6 of the substrate 190 is, for example, about 80 to 100 microns, and a width W3 of the pin 320 is, for example, 100 microns.

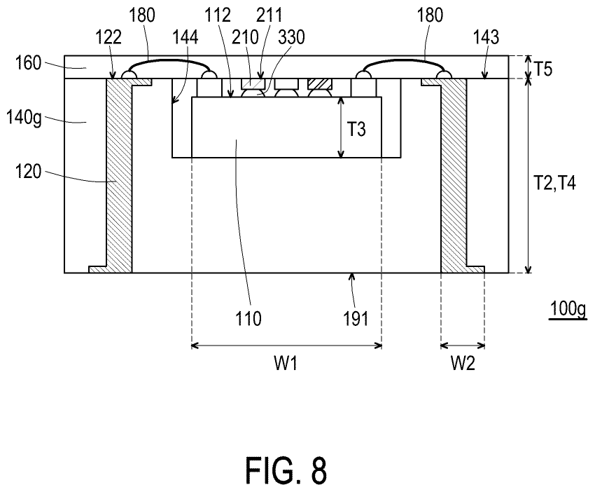

FIG. 5 is a schematic cross-sectional view of a micro light-emitting diode display unit according to another embodiment of the disclosure. Referring to FIG. 5, a micro light-emitting diode display unit 100d of this embodiment is similar to the micro light-emitting diode display unit 100c of FIG. 4, and the main differences between the two are as follows. The micro light-emitting diode display unit 100d of this embodiment further includes a redistribution layer 130, which is disposed between the driving chip 110 and the micro light-emitting diodes 210, and electrically connects the micro light-emitting diodes 210 to the driving chip 110. In this embodiment, the redistribution layer 130 also electrically connects the metal wire 180 to the driving chip 110. In one embodiment, the thickness T1 of the redistribution layer 130 is about 10 to 20 microns.

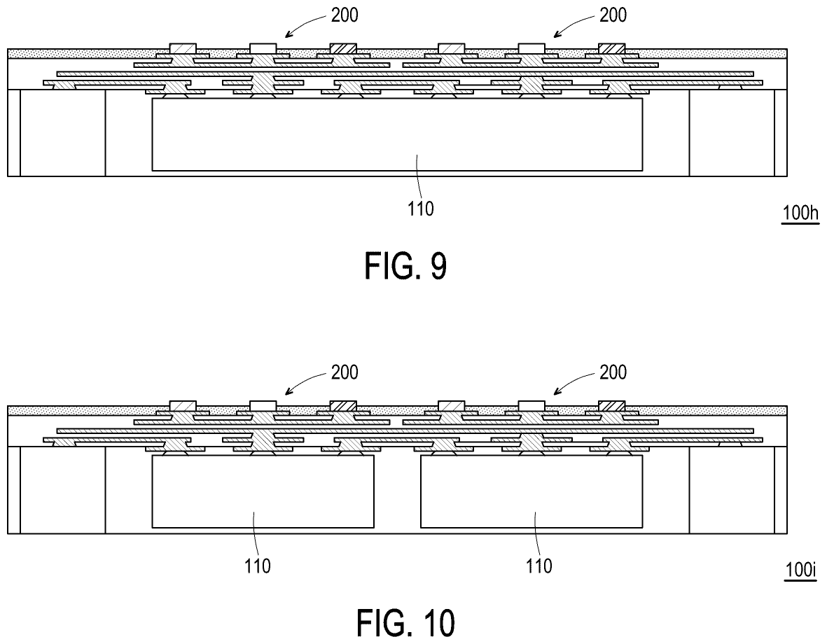

FIG. 6 is a schematic cross-sectional view of a micro light-emitting diode display unit according to still another embodiment of the disclosure. Referring to FIG. 6, a micro light-emitting diode display unit 100e of this embodiment is similar to the micro light-emitting diode display unit 100c of FIG. 4, and the main differences between the two are as follows. The micro light-emitting diode display unit 100e of this embodiment further includes a thin film conductive layer 340, which connects the top portion 112 of the driving chip 110 and a top portion 122 of the conductor 120. The ratio of the height T4 of the conductor 120 to the height (i.e., the thickness T3) of the driving chip 110 falls within a range of 0.9 to 1.1. In this embodiment, an orthogonal projection of the thin film conductive layer 340 on the driving chip 110 is far away from the orthogonal projections of the micro light-emitting diodes 210 on the driving chip 110. In addition, in this embodiment, a packaging material 160e is, for example, glass, which can provide better protection. In this embodiment, the conductor 120 is made of materials such as copper and tin.

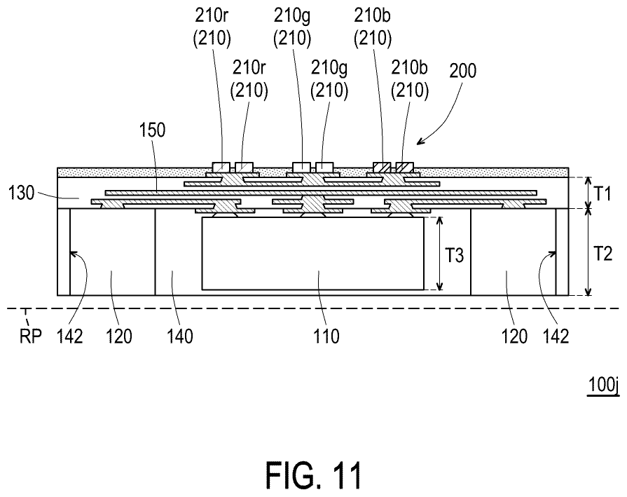

FIG. 7 is a schematic cross-sectional view of a micro light-emitting diode display unit according to yet another embodiment of the disclosure. Referring to FIG. 7, a micro light-emitting diode display unit 100f of this embodiment is similar to the micro light-emitting diode display unit 100e of FIG. 6, and the main differences between the two are as follows. The micro light-emitting diode display unit 100f of this embodiment further includes a redistribution layer 130, which is disposed between the driving chip 110 and the micro light-emitting diodes 210, and electrically connects the micro light-emitting diodes 210 to the driving chip 110. In this embodiment, the redistribution layer 130 also electrically connects the thin film conductive layer 340 to the driving chip 110. In one embodiment, the thickness T1 of the redistribution layer 130 is about 40 microns.

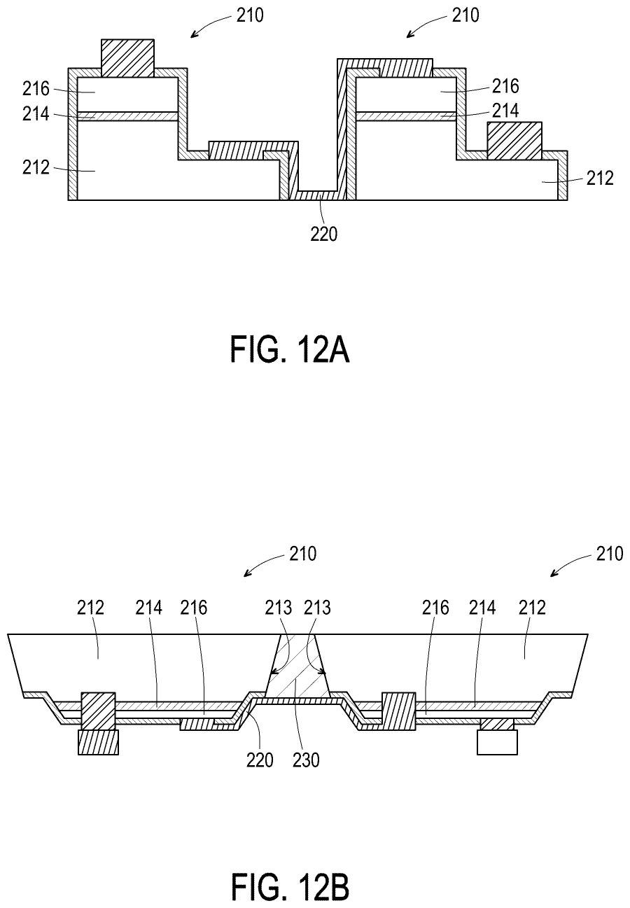

FIG. 8 is a schematic cross-sectional view of a micro light-emitting diode display unit according to another embodiment of the disclosure. Referring to FIG. 8, a micro light-emitting diode display unit 100g of this embodiment is similar to the micro light-emitting diode display unit 100a of FIG. 1, and the main differences between the two are as follows. In the micro light-emitting diode display unit 100g of this embodiment, a carrier 140g has a groove 144, and the driving chip 110 is embedded in the groove 144, so that alignment can be easily achieved and tolerances can be reduced. In addition, in this embodiment, the light-emitting surfaces 211 of the micro light-emitting diodes 210 are flush with an upper surface 143 of the carrier 140g. In other embodiments, the light-emitting surfaces 211 of the micro-light-emitting diodes 210 may also be lower than the upper surface 143 of the carrier 140g.

In this embodiment, the top portion 122 of the conductor 120 is flush with the upper surface 143 of the carrier 140g, and the micro light-emitting diode display unit 100g further includes a metal wire 180 connecting the top portion 112 of the driving chip 110 and the conductor 120.

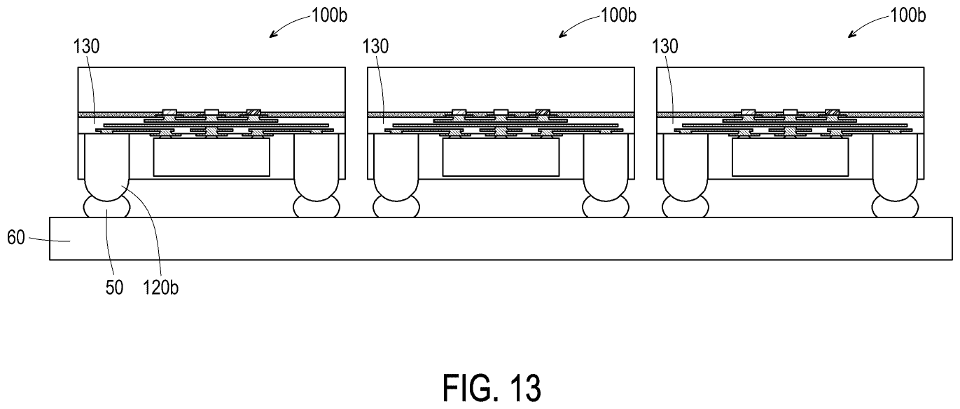

FIG. 9 is a schematic cross-sectional view of a micro light-emitting diode display unit according to still another embodiment of the disclosure. Referring to FIG. 9, a micro light-emitting diode display unit 100h of this embodiment is similar to the micro light-emitting diode display unit 100 of FIG. 1, and the main differences between the two are as follows. The micro light-emitting diode display unit 100h of this embodiment includes multiple pixels 200 (FIG. 9 shows an example of two pixels 200), which are correspondingly disposed on a single driving chip 110, and can be, for example, a matrix arrangement of N×M pixels 200 (N and M being positive integers). In this embodiment, the pixels 200 are electrically connected to the driving chip 110, and the driving chip 110 is used to control and drive the pixels 200.

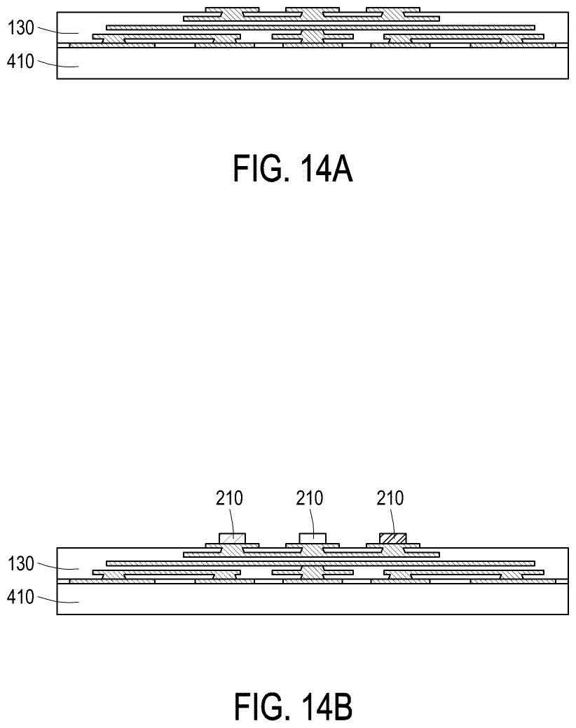

FIG. 10 is a schematic cross-sectional view of a micro light-emitting diode display unit according to yet another embodiment of the disclosure. Referring to FIG. 10, a micro light-emitting diode display unit 100i of this embodiment is similar to the micro light-emitting diode display unit 100 of FIG. 1, and the main differences between the two are as follows. The micro light-emitting diode display unit 100i of this embodiment includes multiple pixels 200 (FIG. 10 shows an example of two pixels 200), which are disposed on multiple driving chips 110 (FIG. 10 shows an example of two driving chips 110). In this embodiment, the driving chips 110 control and drive the pixels 200 respectively.

In other embodiments, the correspondence between the pixels 200 of the micro light-emitting diode display units 100a to 100g of the embodiments of FIG. 2 to FIG. 8 and the driving chip 110 can also be changed to have multiple pixels 200 on a single driving chip 110 as in FIG. 9, or to have multiple pixels 200 on multiple driving chips 110 as in FIG. 10.

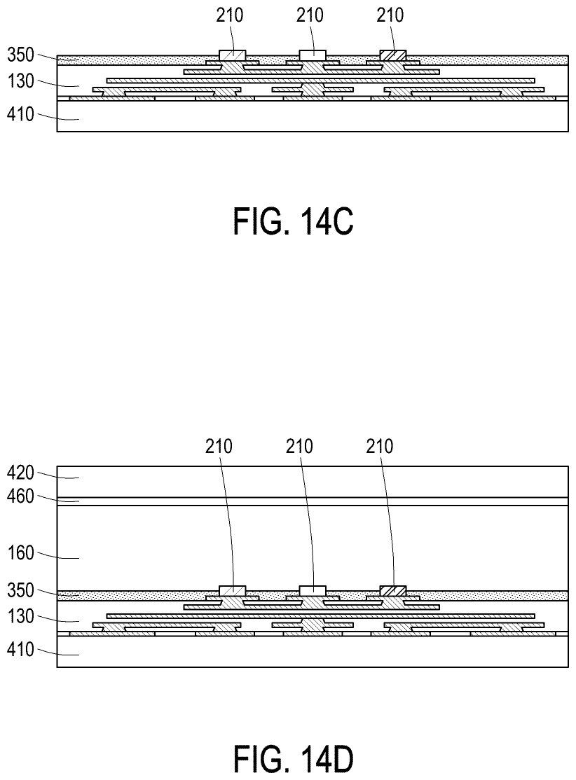

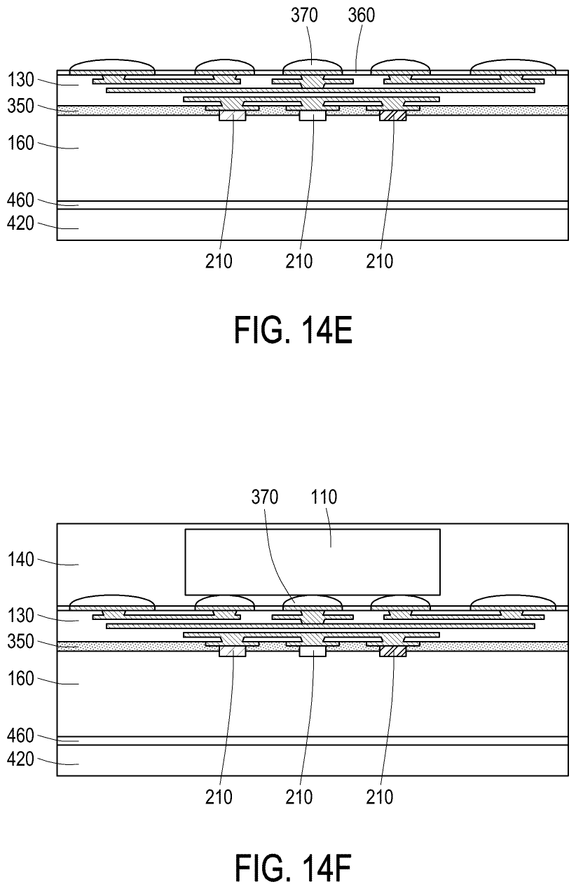

FIG. 11 is a schematic cross-sectional view of a micro light-emitting diode display unit according to another embodiment of the disclosure; FIG. 12A is a schematic cross-sectional view of a group of micro light-emitting diodes in FIG. 11, and FIG. 12B is a schematic cross-sectional view of a group of micro light-emitting diodes of FIG. 11 according to another embodiment. Please refer to FIG. 11, FIG. 12A, and FIG. 12B. A micro light-emitting diode display unit 100j of this embodiment is similar to the micro light-emitting diode display unit 100 of FIG. 1, and the main differences between the two are as follows. In the micro light-emitting diode display unit 100j of this embodiment, the micro light-emitting diodes 210 of the pixel 200 include multiple groups of micro light-emitting diodes 210, and each group of micro light-emitting diodes 210 includes two side-by-side micro light-emitting diodes 210, and the two side-by-side micro light-emitting diodes 210 are electrically connected in series. For example, as shown in FIG. 11, the micro light-emitting diodes 210 include a group of micro light-emitting diodes 210r, a group of micro light-emitting diodes 210g, and a group of micro light-emitting diodes 210b. The group of micro light-emitting diodes 210r includes two side-by-side micro light-emitting diodes 210r, the group of micro light-emitting diodes 210g includes two side-by-side micro light-emitting diodes 210g, and the group of micro light-emitting diodes 210b includes two side-by-side micro light-emitting diodes 210b.

As shown in FIG. 12A and FIG. 12B, each group of micro light-emitting diodes 210 further includes a conductive connection layer 220 that electrically connects the anode of one of the two side-by-side micro light-emitting diodes 210 and the cathode of the other one of the two side-by-side micro light-emitting diodes 210. For example, each micro light-emitting diode 210 includes a first type semiconductor layer 212, a light-emitting layer 214, and a second type semiconductor layer 216, and the conductive connection layer 220 electrically connects the first type semiconductor layer 212 of one of the two side-by-side micro light-emitting diodes 210 and the second type semiconductor layer 216 of the other one of the two side-by-side micro light-emitting diodes 210. One of the first type and the second type is N type, and the other one of the first type and the second type is P type. As shown in FIG. 12B, each group of micro light-emitting diodes 210 further includes a filling structure 230 filled between side walls 213 of the two side-by-side micro light-emitting diodes 210. In this embodiment, the material of the filling structure 230 is, for example, an insulating material.

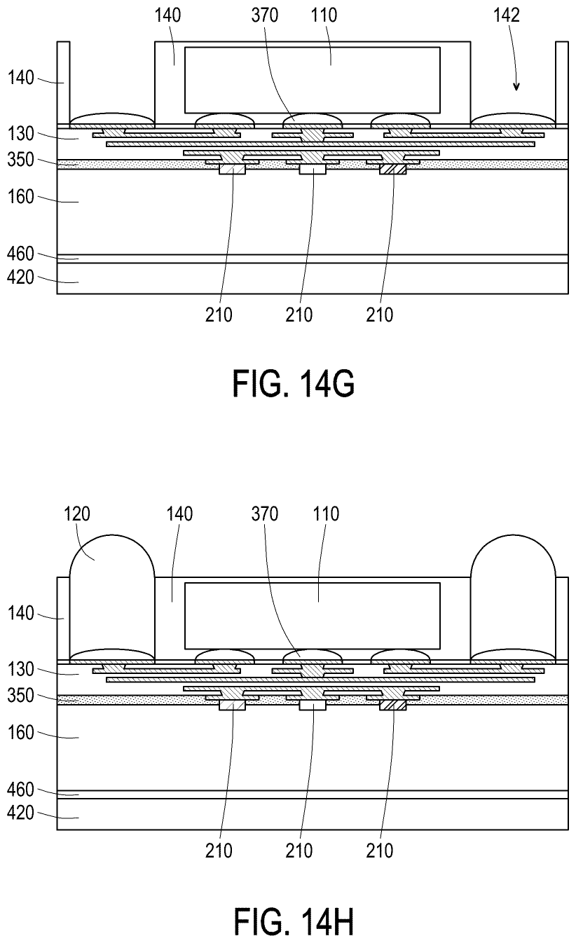

FIG. 13 is a schematic cross-sectional view of multiple micro light-emitting diode display units of FIG. 3 bonded to a circuit substrate. Referring to FIG. 13, the conductors 120b of the multiple micro light-emitting diode display units 100b can be electrically connected to a circuit substrate 60 through a conductive bump 50, and arranged in an array on the circuit substrate 60 to form a micro light-emitting diode display panel. The conductor 120 or the pin 320 of the multiple micro light-emitting diode display units 100, 100a, 100c˜100j of the above other embodiments can also be electrically connected to the circuit substrate 60 through the conductive bump 50 to form a micro light-emitting diode display panel. The circuit substrate 60 is, for example, a circuit board, a glass substrate or a plastic substrate with a circuit, a silicon substrate with a circuit, or other appropriate circuit substrate.

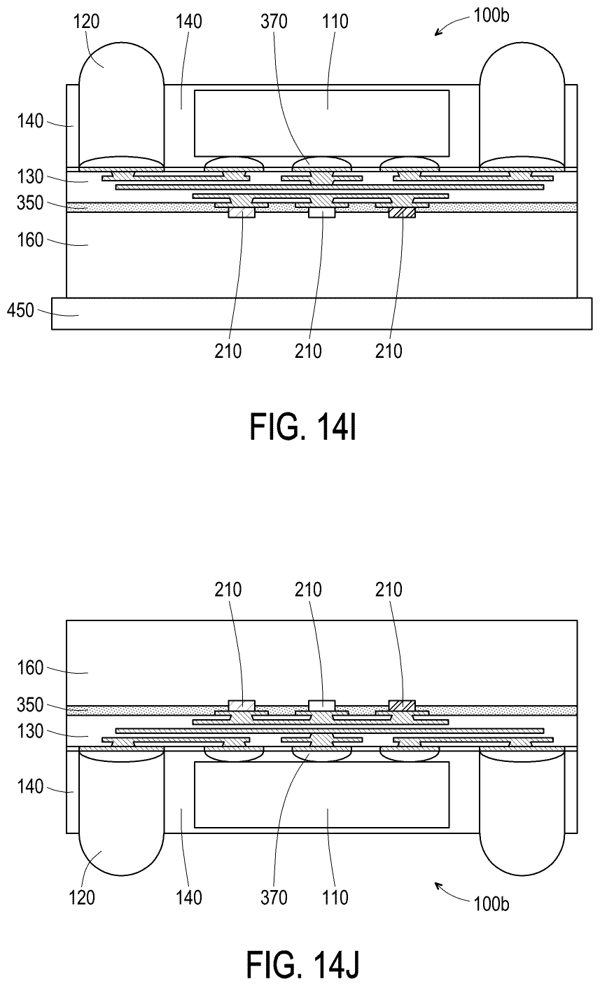

FIG. 14A to FIG. 14J are schematic cross-sectional views illustrating a process of a manufacturing method of a micro light-emitting diode display unit according to an embodiment of the disclosure. Referring to FIG. 14A to FIG. 14J, the manufacturing method of the micro light-emitting diode display unit of this embodiment can be used to manufacture the micro light-emitting diode display unit 100b of FIG. 3. The manufacturing method of the micro light-emitting diode display unit of this embodiment includes the following steps. First, referring to FIG. 14A, a first relay substrate 410 is provided, and a circuit layer (e.g., the redistribution layer 130) is disposed thereon. Next, as shown in FIG. 14B, multiple micro light-emitting diodes 210 are transferred to the first relay substrate 410 and connected to the circuit layer (e.g., the redistribution layer 130). Then, as shown in FIG. 14C, a light-shielding layer 350 is disposed between the micro-light-emitting diodes 210. The light-shielding layer 350 is, for example, a black matrix. After that, as shown in FIG. 14D, a packaging material 160 is disposed to cover the micro light-emitting diodes 210 and the circuit layer (e.g., the redistribution layer 130), and a second relay substrate 420 is disposed on the packaging material 160 through an adhesive layer 460. Next, as shown in FIG. 14E, the first relay substrate 410 is removed. Then, a solder mask layer 360 is disposed on the circuit layer (e.g., the redistribution layer 130). Afterwards, a solder 370 is provided onto the circuit layer (e.g., the redistribution layer 130). Next, as shown in FIG. 14F, a driving chip 110 is soldered to the circuit layer (e.g., the redistribution layer 130). After that, a dry film is used to manufacture a carrier 140. The carrier 140 covers the driving chip 110 and carries the micro light-emitting diodes 210.

After that, the manufacturing method of the micro light-emitting diode display unit of this embodiment may further include the following steps. First, please refer to FIG. 14G. On the side of the driving chip 110, a hole is made in the carrier 140 to form a through hole 142 and expose part of the circuit layer (e.g., the redistribution layer 130). Next, as shown in FIG. 14H, a conductor 120 is disposed in the through hole 142 and is connected to the circuit layer (e.g., the redistribution layer 130). Afterwards, as shown in FIG. 14I, a cutting film 450 is disposed on the surface of the packaging material 160. The cutting film 450 is connected to multiple horizontally arranged micro light-emitting diode display units 100b (which may refer to the micro light-emitting diode display unit 100b in FIG. 3). Next, as shown in FIG. 14J, the horizontally arranged micro light-emitting diode display units 100b are cut and separated. In this way, the manufacturing of the micro light-emitting diode display unit 100b is completed.

To sum up, in the micro light-emitting diode display unit and the manufacturing method thereof according to the embodiments of the disclosure, since the driving chip and the micro light-emitting diode are paired to form a display unit, when such a micro light-emitting diode display unit is later assembled into a display, by assembling the required number of micro light-emitting diode display units, a variety of displays with different resolutions or ratios can be freely formed. In addition, since the micro light-emitting diode display unit has its own driving chip, there is no need to consider matching the number of the micro light-emitting diodes with the number of the driving chips on the circuit substrate as in the conventional technology, and there is no need for the display unit to be additionally aligned with the driving chip on the circuit substrate as in the conventional technology, so that the manufacturing speed of the module section may be effectively increased.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A micro light-emitting diode display unit, comprising:
a driving chip;
at least one pixel, comprising a plurality of micro light-emitting diodes, disposed on a top portion of the driving chip, wherein orthogonal projections of the micro light-emitting diodes are covered by an orthogonal projection of the driving chip; and
a conductor, disposed at an outer side of the driving chip, extending from a side adjacent to the top portion of the driving chip on which the micro light-emitting diodes are disposed to a side far away from the micro light-emitting diodes, and connected to an outside circuit.

2. The micro light-emitting diode display unit according to claim 1, further comprising a carrier, wherein the driving chip is disposed in the carrier.

3. The micro light-emitting diode display unit according to claim 2, wherein the carrier has a through hole, the conductor is disposed in the through hole, and the micro light-emitting diode display unit further comprises a circuit layer disposed between the micro light-emitting diodes and the driving chip and connecting the micro light-emitting diodes, the conductor, and the driving chip.

4. The micro light-emitting diode display unit according to claim 2, further comprising a thin film conductive layer connecting the top portion of the driving chip and a top portion of the conductor, wherein a ratio of a height of the conductor to a height of the driving chip falls within a range of 0.9 to 1.1.

5. The micro light-emitting diode display unit according to claim 4, wherein an orthogonal projection of the thin film conductive layer on the driving chip is far away from the orthogonal projections of the micro light-emitting diodes on the driving chip.

6. The micro light-emitting diode display unit according to claim 2, wherein the carrier has a groove, and the driving chip is embedded in the groove.

7. The micro light-emitting diode display unit according to claim 6, wherein a plurality of light-emitting surfaces of the micro-light-emitting diodes are flush with or lower than an upper surface of the carrier.

8. The micro light-emitting diode display unit according to claim 6, wherein the top portion of the conductor is flush with the upper surface of the carrier, and the micro light-emitting diode display unit further comprises a metal wire connecting the top portion of the driving chip and the conductor.

9. The micro light-emitting diode display unit according to claim 2, wherein the circuit layer is a redistribution layer, and a thickness of the redistribution layer is less than 50% of a thickness of the carrier.

10. The micro light-emitting diode display unit according to claim 2, wherein a thickness of the driving chip is greater than 70% of a thickness of the carrier.

11. The micro light-emitting diode display unit according to claim 1, wherein the at least one pixel is a plurality of pixels, and the pixels are correspondingly disposed on a single driving chip.

12. The micro light-emitting diode display unit according to claim 1, wherein the micro light-emitting diodes of the pixel comprise a plurality of groups of micro light-emitting diodes, each group of the micro light-emitting diodes comprises two side-by-side micro light-emitting diodes, and the two side-by-side micro light-emitting diodes are electrically connected in series.
